(19) United States
(12) Patent Application Publication
(10) Pub. No.: US 2005/0112807 A1
(43) Pub. Date: May 26, 2005

(54) Thin film transistor, method of fabricating the same and flat panel display using thin film transistor

(76) Inventors: Jae-Bon Koo, Yongin-si (KR); Sang-Gul Lee, Gyeonggi-do (KR)

Correspondence Address: MCGUIREWOODS, LLP, 1750 TYSONS BLVD, SUITE 1800, MCLEAN, VA, 22102, US

(21) Appl. No.: 10/992,202

(22) Filed: Nov. 19, 2004

(30) Foreign Application Priority Data
Nov. 25, 2003 (KR) 2003-84237

(51) Int. Cl. H01L 21/00; H01L 21/84; H01L 27/148; H01L 29/768; H01L 21/336

(52) U.S. Cl. 438/151; 438/300; 257/228

(57) ABSTRACT

Disclosed is a thin film transistor with a GOLDD structure, a method of fabricating the same, and a flat panel display using the same. Such a thin film transistor may include an active layer formed on an insulating substrate and may have source/drain regions and a channel region, a gate insulating film formed on the active layer, and a gate electrode formed on the gate insulating film. The gate electrode may be formed of a first gate pattern and a second gate pattern covering the first gate pattern. The source/drain regions may each have an LDD region, and the LDD regions may overlap (or lie partially under) the gate electrode.

### CROSS-REFERENCE TO RELATED APPLICATION

This application claims the benefit of Korea Patent Application No. 2003-84237 filed on Nov. 25, 2003, the disclosure of which is hereby incorporated herein by reference in its entirety.

### BACKGROUND OF THE INVENTION

1. Field of the Invention

The present invention relates to a thin film transistor (TFT), a method of fabricating the same and a flat panel display using the TFT. More particularly the invention may relate to a TFT having a gate overlapped lightly doped drain (GOLDD) structure, a method of fabricating the same and a flat panel display using such a TFT.

2. Description of the Related Art

An active-matrix flat panel display using a TFT as a switching element comprises pixel-driving TFTs formed in each pixel and driving the pixels. It also includes driving-circuit TFTs driving the pixel-driving TFTs and transmitting a signal to a scan line (gate line) and a signal line (data line).

Polycrystalline silicon TFTs may be fabricated at a temperature similar to that for fabricating an amorphous silicon TFT due to the advance of crystallization technology using laser. This polycrystalline silicon may allow electrons or holes to have higher mobility as compared with the amorphous silicon TFT. Thus it is possible to realize complementary metal-oxide semiconductor (CMOS) TFTs having n- and p-channels. Accordingly, polycrystalline silicon can be used to form both the pixel-driving TFTs and the driving-circuit TFTs on a large sized insulating substrate.

In the polycrystalline silicon CMOS TFT, an n-channel metal oxide semiconductor (NMOS) TFT generally uses phosphorus (P) as a dopant. Phosphorus (P) has an atomic weight heavier than boron (B). Boron (B) is generally used in a p-channel metal oxide semiconductor (PMOS) TFT. As a result, the silicon crystal lattice of such a CMOS is likely to become damaged at a predetermined region and the damaged region is not completely recoverable in the sequential activating process.

Such a damaged region decreases the mobility of electrons. This is because of hot carrier stress. Hot carrier stress occurs when electrons flowing through a gate insulating film or metal-oxide semiconductor (MOS) interface are accelerated from a source region to a drain region. Therefore, the damaged region may have a negative effect on circuit operation of a flat panel display, and may increase off-current.

To solve the foregoing problems, there have been proposed various structures such as an off-set structure, a lightly doped drain (LDD) structure, and others. In the case of an off-set structure, an off-set region is provided to form an imperfect doping region on a predetermined region between the gate and the source/drain regions, so that an electric field applied to a junction area is reduced by great resistance due to the off-set region, thereby decreasing the off-current. In the LDD structure, an LDD may be formed by lowering the doping concentration applied to a predetermined region between the source and drain regions to decrease the off-current and to minimize the on-current reduction.

However, as the low temperature poly silicon (LTPS) technology is highly integrated, the conventional off-set and LDD structures are of limited enhancement to the reliability of a short channel device. To overcome the limit, a thin film transistor with a gate overlapped lightly doped drain (GOLDD) structure has been proposed.

Hereinbelow, a basic GOLDD structure will be described with reference to accompanying drawings.

FIGS. 1A, 1B, 1C, and ID are cross-sectional views for illustrating a fabrication process of a conventional thin film transistor with a GOLDD structure.

As shown in FIG. 1A, a buffer layer 110 may be formed on an insulating substrate 100, and then an amorphous silicon film may be deposited on the buffer layer 110 and crystallized into a polycrystalline silicon film. Thereafter, an active layer 120 may be formed by patterning the polycrystalline silicon film.

After forming the active layer 120, a gate insulating film 130 may be formed on the entire surface of the insulating substrate 100 formed with the active layer 120.

After forming the gate insulating film 130, a first photoresist pattern 140 may be is formed for doping low concentration impurities having a predetermined conductive type (e.g., for LDD doping).

After forming the first photoresist pattern 140, the low concentration impurities may be doped using the first photoresist pattern 140 as a mask, such that low concentration source/drain regions 123S, 123D are formed on the active layer 120. At this time, a region between the low concentration source/drain regions 123S and 123D may be used as a channel region 121 of the thin film transistor.

As shown in FIG. 1B, after forming the low concentration source/drain regions 123S, 123D on the active layer 120 through the lightly doping, the first photoresist pattern 140 may be removed, and a gate electrode material film 150 may be formed on the gate insulating film 130. Then, a second photoresist pattern 160 may be created in order to form a gate electrode.

The second photoresist pattern 160 may be formed partially overlapping the low-concentration source/drain regions 123S and 123D. Further, the overlapped region may not be narrower than about 0.5 μm depending on resolution of a stepper.

As shown in FIG. 1C, a gate electrode 155 may be formed by patterning the gate electrode material film 150, using the second photoresist pattern 160 as the mask. Thus, the gate electrode 155 may be formed partially overlapping the respective low concentration source/drain regions 123S and 123D due to the second photoresist pattern 160.

After forming the gate electrode 155 to overlap the respective low-concentration source/drain regions 123S and 123D, high-concentration impurities are doped onto the active layer 120 through the gate electrode 155 used as mask, thereby forming high-concentration source/drain regions 125S and 125D.

As shown in FIG. 1D, an interlayer insulating film 170 having contact holes 171, 175 through which the high-concentration source/drain regions 125S, 125D are partially exposed is formed on an entire surface of the insulating substrate 100 with the gate electrode 155. Then, source/drain electrodes 181, 185 are formed to be electrically connected to the high-concentration source/drain regions 125S, 125D through the contact holes 161, 165, thereby finally forming the thin film transistor with the GOLDD structure.

However, in the conventional thin film transistor with the GOLDD structure, it may be difficult to reduce the low concentration source/drain regions overlapping with the gate electrode. That is, it is difficult to reduce the width of an LDD range to about 0.5 μm or less because of the resolution of the stepper.

Further, in the conventional thin film transistor with the GOLDD structure, the low concentration impurities are doped using a photoresist mask and then the high-concentration impurities are doped after forming the gate electrode. Thus a mask for doping the low concentration impurities is required. Additionally the gate electrode may be easily susceptible to defective alignment.

### SUMMARY OF THE INVENTION

The present invention provides a thin film transistor with a GOLDD structure, a method of fabricating the same, and a flat panel display using the same. In such a structure, the gate electrode may be formed by a first gate pattern and a second gate pattern covering the first gate pattern. This allows easy adjustment of the width of an LDD region and may prevent defective alignment of the gate electrode.

The present invention separately provides a thin film transistor comprising an is active layer formed on an insulating substrate and having source/drain regions and a channel region, a gate insulating film formed on the active layer, and a gate electrode formed on the gate insulating film and formed by a first gate film and a second gate film covering the first gate pattern, wherein the source/drain regions has an LDD region, and the LDD region overlaps the gate electrode.

The second gate pattern is preferably made of a transparent conductive material, and more preferably made of any one of indium tin oxide (ITO), indium zinc oxide (IZO), zinc oxide (ZnO), and indium oxide (In₂O₃).

The second gate pattern preferably is about 2 μm or less wide, and more preferably about 1 μm or less wide.

The LDD region is preferably formed horizontally under the second gate pattern formed at the sides of the first gate pattern, and is preferably narrower than the second gate pattern formed at the sides of the first gate pattern.

The LDD region is preferably about 2 μm or less wide, and more preferably about 1 μm or less wide.

The present invention separately provides a method of fabricating a thin film transistor. They form an active layer on an insulating substrate. They form a gate insulating film on the active layer. They form a first gate pattern on the gate insulating film. They lightly dope the active layer, using the first gate pattern as a mask. They form a gate electrode of the first gate pattern and a second gate pattern covering the first gate pattern. They form source/drain regions by highly doping the active layer, using the gate electrode as a mask. The source/drain regions may have an LDD region, and the LDD region may overlap the gate electrode.

Forming the gate electrode may include further steps. They form a conductive material film on an entire surface of the insulating substrate with the first gate pattern. They form a photoresist on the entire surface of the insulating substrate. They form a photoresist pattern for the second gate pattern by performing back exposure to the insulating substrate. They form the second gate pattern covering the first gate pattern by patterning a transparent gate pattern, using the photoresist pattern as a mask.

The present invention separately provides an active matrix flat panel display or an active matrix organic electroluminescence display, which uses the foregoing thin film transistor.

### BRIEF DESCRIPTION OF THE DRAWINGS

The above and other features and advantages of the present invention will become more apparent to those of ordinary skill in the art by describing in detail preferred embodiments thereof with reference to the attached drawings.

FIGS. 1A, 1B, 1C, and 1D are cross-sectional views for illustrating a fabrication process of a conventional thin film transistor with a GOLDD structure.

FIGS. 2A, 2B, 2C, 2D, and 2E are cross-sectional views for illustrating a fabrication process of a thin film transistor with a GOLDD structure according to an embodiment of the present invention.

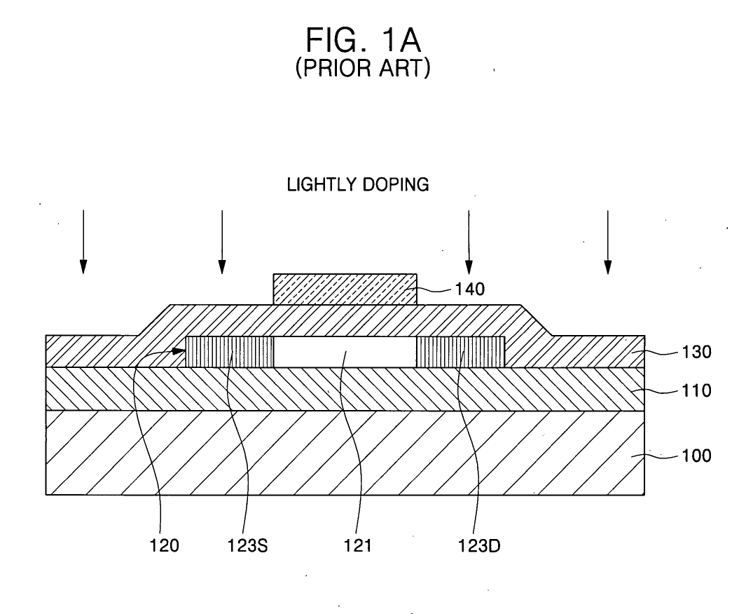

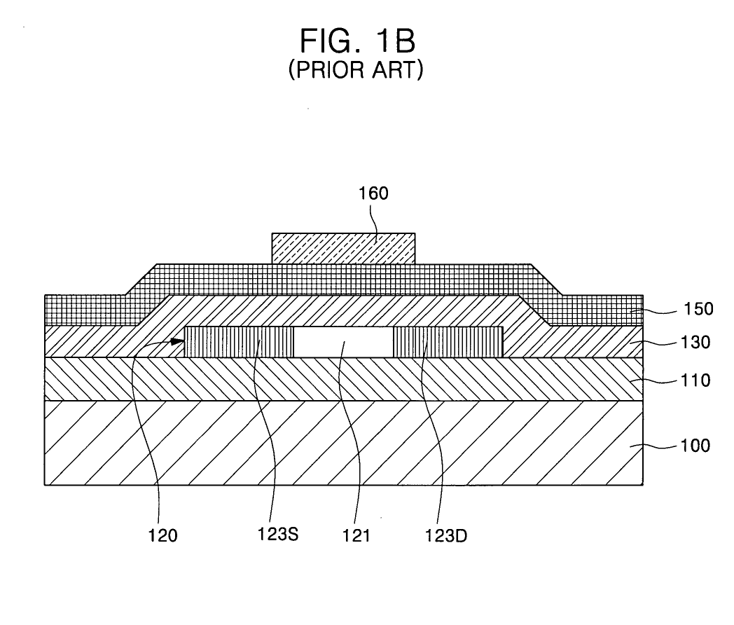

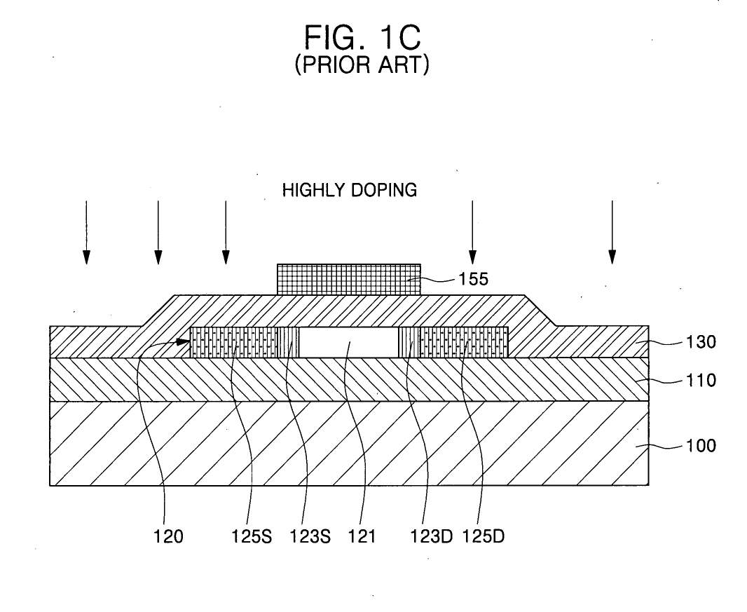

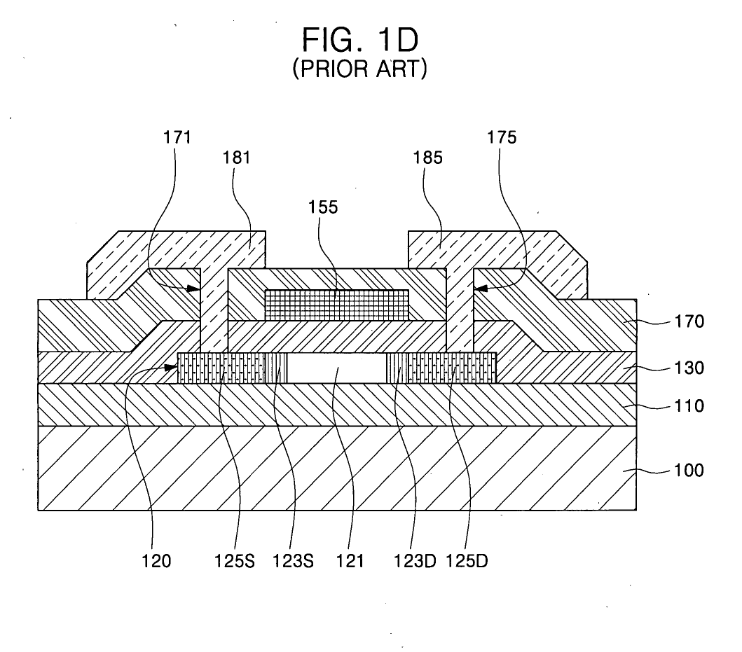

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. In the drawings, the thickness of layers and regions is are exaggerated for clarity. Like numbers refer to like elements throughout the specification.

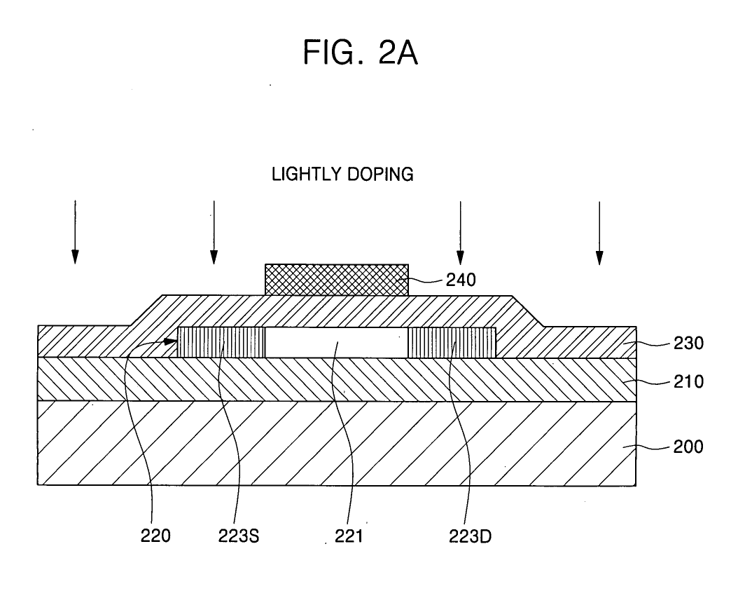

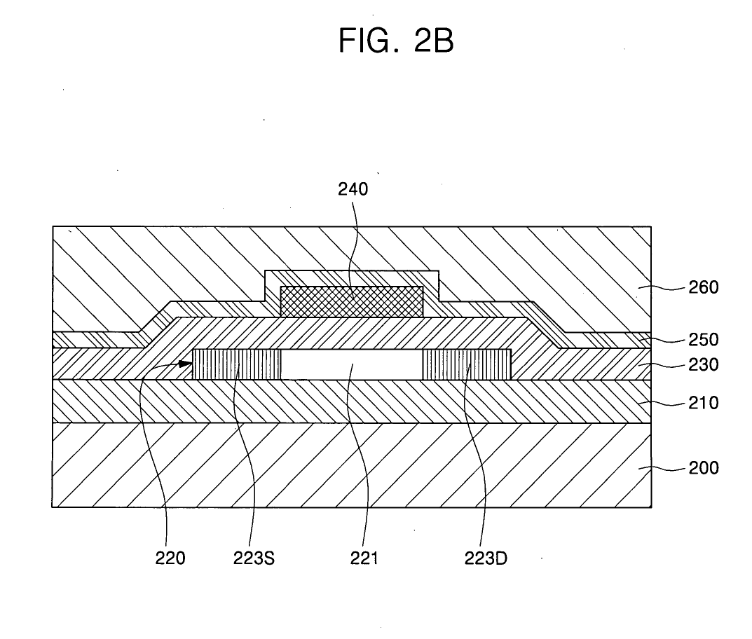

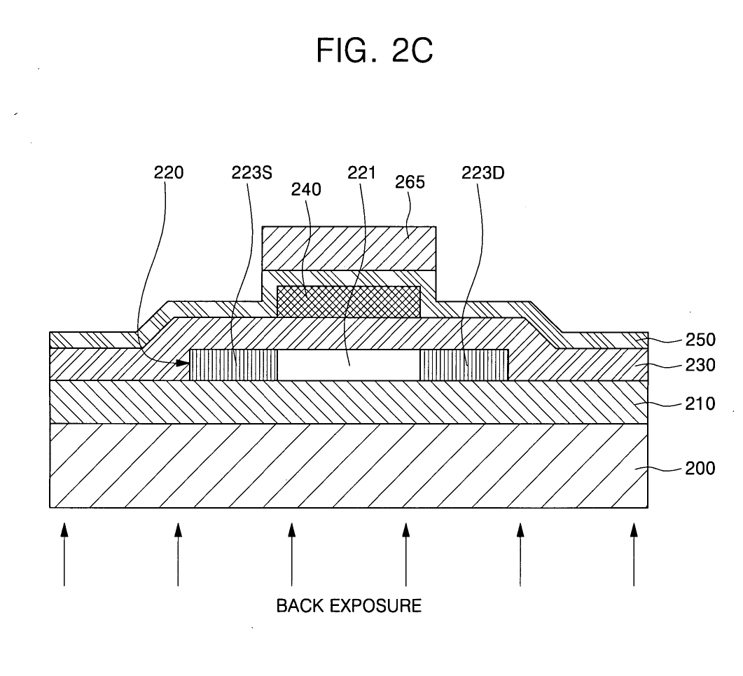

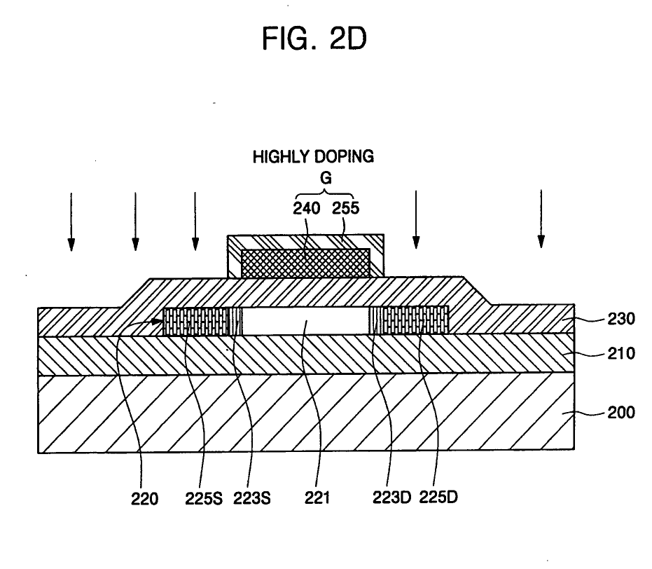

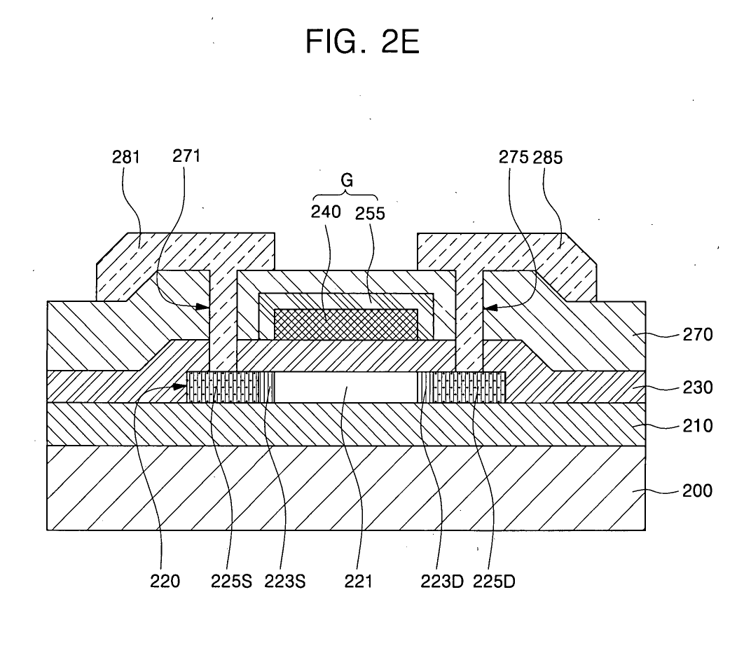

FIGS. 2A, 2B, 2C, 2D, and 2E are cross-sectional views for illustrating a fabrication process of a thin film transistor with a GOLDD structure according to an embodiment of the present invention.

A thin film transistor with a GOLDD structure according to an embodiment of the present invention may have a structure in which a gate electrode formed with a first gate pattern and a transparent second gate pattern covering the first gate pattern is overlapped with an LDD region as a lightly doping region provided in an active layer.

As shown in FIG. 2A, a buffer layer (diffusion barrier) 210 may be formed on an insulating substrate 200 by plasma enhanced chemical vapor deposition (PECVD), low-pressure chemical vapor deposition (LPCVD), sputtering method, or the like, so as to prevent impurities such as a metal ion or the like from being diffused and infiltrated into the active layer (amorphous silicon).

An amorphous silicon film may be deposited on the buffer layer 210 by PECVD, LPCVD, sputtering or the like. Then, a dehydrogenation process may be performed in a vacuum furnace. When the amorphous silicon film is deposited by the sputtering method, the dehydrogenation process may be omitted.

Thereafter, a crystallization process of applying high energy to the amorphous silicon film is performed to crystallize the amorphous silicon, thereby forming a polycrystalline silicon film. Preferably, one of the following methods may be used in the crystallization process: an excimer laser annealing (ELA) process, a metal induced crystallization (MIC) process, a metal induced lateral crystallization (MILC) process, a sequential lateral solidification (SLS) process, a solid phase crystallization (SPC) process, or the like.

After forming the polycrystalline silicon film, an active layer 220 may be formed by patterning the polycrystalline silicon film.

Thereafter, a gate insulating film 230 may be deposited on the active layer 220, and a first conductive metal film may be deposited on the gate insulating film 230. Then, a first gate pattern 240 may be formed by patterning the conductive metal film.

After forming the first gate pattern 240, impurities having a predetermined conductive type may be lightly doped using the first gate pattern 240 as a mask. In other words, lightly doped drain (LDD) is doped using the first gate pattern 240 as a mask, to form low concentration source/drain regions 223S and 223D. At this time, a region between the low concentration source/drain regions 123S and 123D may function as a channel region 221 of the thin film transistor.

As shown in FIG. 2B, a second conductive material film 250 may be formed on the entire surface of the insulating substrate 200 formed with the first gate pattern 240 so as to form a second gate pattern.

The second conductive material film 250 may preferably be made of a transparent conductive material such as indium tin oxide (ITO), indium zinc oxide (IZO), zinc oxide (ZnO), indium oxide (In₂O₃), or the like. The second conductive material film 250 may be about 2 μm or less wide, and more preferably less than about 1 μm wide. These characteristics may be advantageous to using a back exposure process to form a subsequent photoresist pattern.

Next, a photoresist 260 may be formed on the entire surface of the insulating substrate 200. This may be useful in assisting etching process for the second conductive material film 250.

As shown in FIG. 2C, after forming the photoresist 260, the back exposure process may be performed below the insulating substrate 200, thereby forming a photoresist pattern 265. That is, the photoresist pattern 265 may be formed by the back exposure process.

Forming the photoresist pattern 265 by the back exposure process may improve the precision of the photoresist pattern 265 that may depend on resolution of a stepper. Hence, the width of an LDD region of a GOLDD structure to be thereafter formed is not limited by the resolution of a stepper. Thus the LDD region can be about 0.5 μm or less wide and be adjusted by ∪ units.

As shown in FIG. 2D, the second gate pattern 255 is formed covering the first gate pattern 240 by etching the second conductive material film 250, using the photoresist pattern 265 as a mask, so that a gate electrode G is formed of both the first gate pattern 240 and the second gate pattern 255.

After forming the gate electrode G of both the first gate pattern 240 and the second gate pattern 255, the photoresist pattern 265 may be removed. Then, the active layer 220 may be highly doped using the gate electrode G as a mask. High-concentration source/drain regions 225S and 225D may thus be formed.

After these processes, the low concentration source/drain regions 223S and 223D formed under the second gate pattern 255 formed at the sides of the first gate pattern 240 are not highly doped. This is because the second gate pattern 255 effectively masks photoresist 265 in the area immediately to the right and left of first gate pattern 240. Thus the low concentration source/drain regions 223S and 223D remain in a lightly doped state and functioned as the LDD region. Consequently, the gate electrode G overlaps the lightly doped regions 223S and 223D (in this case, the LDD region), thereby forming the GOLDD structure. Here, the LDD region is formed under the second gate pattern 255 formed at the sides of the first gate pattern 240.

Further, the width of the LDD region of the GOLDD structure is determined by the thickness of the second gate pattern 255 formed at the sides of the first gate pattern 240. That is to say, the width of the LDD region formed overlapping with the gate electrode G corresponds with than the thickness of the second gate pattern 255 formed at the sides of the first gate pattern 240. It is preferably that the LDD region is about 2 μm or less wide, and more preferably about 1 μm or less wide.

As shown in FIG. 2E, after forming the high-concentration source/drain regions 225S, 225D, an interlayer insulating film 270 may be formed on the entire surface of the insulating substrate 200 and patterned to have contact holes 271, 275 through which the high-concentration source/drain regions 225S, 225D may be partially exposed.

After forming the contact holes 271, 275, a predetermined conductive film may be deposited on the entire surface of the insulating substrate 200 and patterned to form source/drain electrodes 281, 285 that may be electrically connected to the high-concentration source/drain regions 225S, 225D. This may complete the thin film transistor with the GOLDD structure.

As described above, in the thin film transistor with the foregoing GOLDD structure, no additional mask may be needed for the lightly doping. This may prevent defective alignment of the gate electrode G.

Also, the GOLDD structure may be formed using the gate electrode G formed by the first gate pattern 240 and the second gate pattern covering the first gate pattern 240. Accordingly, the width of the LDD region can be adjusted by adjusting the thickness of the second gate pattern 255 formed at the sides of the first gate pattern 240. Hence, it is possible to form the LDD region that is about 2 μm or less wide, preferably about 1 μm or less wide.

Further, a method of fabricating an active matrix flat panel display such as an active matrix liquid crystal display (LCD) and an active matrix organic electro luminescence display (OLED) can be implemented using a thin film transistor with the foregoing GOLDD structure.

As described above, according to the present invention, the following are provided: a thin film transistor with a GOLDD structure, a method of fabricating the same, and a flat panel display incorporating such a transistor. In an embodiment of the present invention a gate electrode include a first gate pattern and a second gate pattern covering the first gate pattern. This kind of gate pattern may permit the width of an LDD region to be easily adjusted and may prevent defective alignment of the gate electrode.

While the present invention has been described with reference to an example embodiment, it is understood that the disclosure has been made for purpose of illustrating the invention by way of examples and is not limited to limit the scope of the invention. One skilled in the art can change the described embodiment of the present invention without departing from the scope of the invention.

1. A thin film transistor, comprising:
an active layer formed on an insulating substrate and having source/drain regions and a channel region;
a gate insulating film formed on the active layer; and
a gate electrode formed on the gate insulating film, and comprising a first gate pattern and a second gate pattern covering the first gate pattern,
wherein at least any one of the source/drain regions has an LDD region, and the LDD region horizontally overlaps the gate electrode.

2. The thin film transistor of claim 1, wherein the second gate pattern is made of a transparent conductive material.

3. The thin film transistor of claim 2, wherein the second gate pattern comprises at least one material selected from the group of indium tin oxide (ITO), indium zinc oxide (IZO), zinc oxide (ZnO), and indium oxide (In₂O₃).

4. The thin film transistor of claim 1, wherein the second gate pattern is about 2 μm or less thick.

5. The thin film transistor of claim 4, wherein the second gate pattern is about 1 μm or less thick.

6. The thin film transistor of claim 1, wherein the LDD region is formed vertically under the second gate pattern formed on at least two sides of the first gate pattern.

7. The thin film transistor of claim 1, wherein the LDD region is narrower than the second gate pattern formed at the sides of the first gate pattern.

8. The thin film transistor of claim 1, wherein the LDD region is about 2 μm or less wide.

9. The thin film transistor of claim 8, wherein the LDD region is about 1 μm or less wide.

10. A method of fabricating a thin film transistor, comprising:
forming an active layer on an insulating substrate;
forming a gate insulating film on the active layer;
forming a first gate pattern on the gate insulating film;
doping the active layer lightly, while masking a portion of the active layer with the first gate pattern as a mask;
forming a gate electrode of the first gate pattern and a second gate pattern covering the first gate pattern; and
forming source/drain regions by highly doping the active layer, while masking a portion of the active layer with the gate electrode,
wherein at least one of the source/drain regions has an LDD region, and the LDD region horizontally overlaps the gate electrode.

11. The method of claim 10, wherein forming the gate electrode further comprises:
forming a conductive material film on an entire surface of the insulating substrate with the first gate pattern;
forming a photoresist on the entire surface of the insulating substrate;
forming a photoresist pattern for the second gate pattern by performing back exposure to the insulating substrate; and
forming the second gate pattern covering the first gate pattern by patterning a transparent gate pattern, using the photoresist pattern as mask.

12. The method of claim 10, wherein the second gate pattern is made of a transparent conductive material.

13. The method of claim 12, wherein the second gate pattern is made of any one of indium tin oxide (ITO), indium zinc oxide (IZO), zinc oxide (ZnO), and indium oxide (In₂O₃).

14. The method of claim 10, wherein the second gate pattern is about 2 μm or less wide.

15. The method of claim 14, wherein the second gate pattern is about 1 μm or less wide.

16. The method of claim 10, wherein the LDD region is formed under the second gate pattern formed on at least two sides of the first gate pattern.

17. The method of claim 10, wherein the LDD region has a width that corresponds with the thickness of the second gate pattern formed at the sides of the first gate pattern.

18. The method of claim 10, wherein the LDD region is about 2 μm or less wide.

19. The method of claim 18, wherein the LDD region is about 1 μm or less wide.

20. An active matrix flat panel display using a thin film transistor wherein the thin film transistor comprises:
an active layer formed on an insulating substrate and having source/drain regions and a channel region;
a gate insulating film formed on the active layer; and
a gate electrode formed on the gate insulating film, and comprising a first gate pattern and a second gate pattern covering the first gate pattern,
wherein at least any one of the source/drain regions has an LDD region, and the LDD region horizontally overlaps the gate electrode.

21. The active matrix flat panel display of claim 20, wherein the flat panel display is a liquid crystal display or an organic electroluminescent display.
